(19) United States
(12) Patent Application Publication
(10) Pub. No.: US 2023/0069183 A1
(43) Pub. Date: Mar. 2, 2023

(54) STACKED STRUCTURE WITH INTERPOSER

(71) Applicant: INVENSAS LLC, San Jose, CA (US)

(72) Inventor: Belgacem Haba, Saratoga, CA (US)

(21) Appl. No.: 17/823,430

(22) Filed: Aug. 30, 2022

Related U.S. Application Data
(60) Provisional application No. 63/239,783, filed on Sep. 1, 2021.

(51) Int. Cl. H01L 23/40; H01L 23/485; H01L 25/065

(52) U.S. Cl. CPC H01L 23/4012; H01L 23/485; H01L 25/0652; H01L 2023/4087

(57) ABSTRACT

Stacked structures having interposers adhered to packaging substrates are disclosed. In one example, a stacked structure can include a laminate substrate. The stacked structure can also include an interposer mounted on the laminate substrate without solder, for example by an electrically nonconductive adhesive layer. A plurality of conductive vias can be extending through the interposer, and through the nonconductive adhesive layer if present, and connecting to the laminate substrate. The stacked structure can also include a redistribution layer (RDL) adjacent to the interposer. The RDL can be configured to electrically connect to an electronic device. Methods for forming such stacked structures are also disclosed.

### CROSS-REFERENCE TO RELATED APPLICATIONS

This application claims priority to U.S. Provisional Application No. 63/239,783, filed Sep. 1, 2021, titled “BONDED STRUCTURE WITH INTERPOSER”, the disclosure of which is incorporated herein by reference in its entirety for all purposes.

### BACKGROUND

### Field

The field generally relates to stacked structures, and in particular, to stacked electronic components for packaging or mounting to a board, including interposers and packaging substrates.

### Description of the Related Art

Packaging multiple dies into an electronic system may involve assembling multiple dies onto a substrate with solder balls, thermal conductive bonding (TCB), etc. As assemblies become finer, it becomes harder to connect numerous contacts to the substrate. Introducing a redistribution layer (RDL) between the substrate and the dies having fine lines and spacings can provide better connectivity. However, RDL may have a roughly 1-micron alignment spacing. At the 1-micron scale, the substrate, e.g., printed circuit board (PCB), tends to be wavy and not have a smooth surface, so it is hard to align a RDL to the substrate.

### BRIEF DESCRIPTION OF THE DRAWINGS

Specific implementations will now be described with reference to the following drawings, which are provided by way of example, and not limitation.

FIG. 1 schematically shows an example stacked structure according to some embodiments of the disclosed technology.

FIGS. 2A-2E are schematic cross sections illustrating an example process of forming an stacked structure shown in FIG. 1.

FIGS. 3A-3F are schematic cross sections illustrating another example process of forming an stacked structure shown in FIG. 1.

FIGS. 4A-4D are schematic cross sections illustrating yet another example process of forming an stacked structure shown in FIG. 1.

FIGS. 5A-5D are schematic cross sections showing example stacked structures with more than one interposer.

FIGS. 6A-6B are schematic cross sections illustrating example uses of the disclosed stacked structures in packages systems.

### DETAILED DESCRIPTION

Packaging multiple dies into an electronic system may involve first assembling dies on an interposer and then soldering the dies and interposer assembly onto a packaging substrate, which in turn can be mounted to a system board. The interposer with a redistribution layer on top can provide fine lines and spacings. However, the soldering process may involve raising the temperature then lowering the temperature at the interface, which creates stresses at the interface. There remains a continuing need for simplifying packaging processes and improving electrical performances of packaged electronic systems.

In some embodiments, the present disclosure provides a way of assembling interposers with a packaging substrate without the use of solder. In some embodiments, the present disclosure provides a stacked structure having more than one interposer per substrate, adhered to the packaging substrate without solder. The stacked structure may be used in multi-chip modules having more than one substrate.

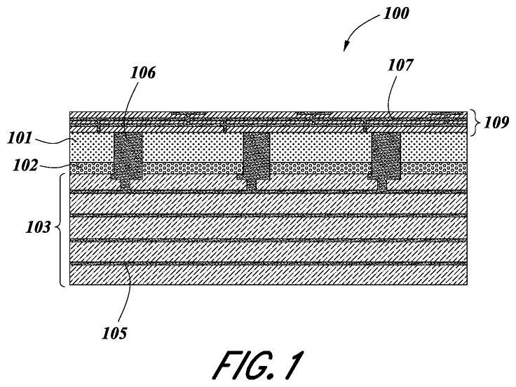

FIG. 1 shows a stacked structure 100 having a substrate, e.g., an interposer, adhered to a packaging substrate. The stacked structure 100 can include a laminate substrate 103 (e.g., PCB or ceramic) and an interposer 101 mounted on the laminate substrate 103 by an electrically nonconductive adhesive layer 102, die attach material (e.g. die attach film or paste) or underfill. In some embodiments, the interposer substrate, or at least the bulk material thereof, has a coefficient of thermal expansion (CTE) that is below 10 ppm/° C., and more particularly below 7 ppm/° C. In some embodiments, the adhesive layer 102 may be a composite which includes an epoxy that is filled with low coefficient of thermal expansion (CTE) particles, such as glass beads, to lower the overall CTE of the composite after hardening. The laminate substrate 103 can comprise a plurality of nonconductive layers with embedded conductive traces 105. The stacked structure 100 can further include a redistribution layer (RDL) 109 on the interposer 101. The RDL 109, having conductors 107 (pads, vias, traces, etc.) embedded in an insulating material, may be configured to electrically connect to an electronic device. In some embodiments, the insulating material of the RDL 109 can be a deposited organic material, such as polymers (e.g., polyamide, polyimide, BCB, etc.). In other embodiments, the insulating material of the RDL 109 can be a deposited inorganic material such as is suitable for subsequent direct bonding with similar insulating materials or with semiconductor materials (e.g., silicon oxide, silicon nitride, silicon oxynitride, silicon carbide, silicon carbonitride, etc.). In some embodiments, the redistribution layer 109 has a line spacing less than 5 microns. A plurality of conductive vias 106 can extend through the interposer 101 to connect with the conductors 107 of the RDL 109 as shown, and can further extend through the redistribution layer 109 (see FIGS. 4A-4D and attendant description). In some embodiments, the RDL 109 is disposed over the plurality of conductive vias 106. In some embodiments, an additional redistribution layer is further arranged between the interposer 101 and the laminate substrate 103.

The interposer 101 can include a nonconductive material formed of glass, a semiconductor material (e.g., silicon, GaAs, InP, etc.) or ceramic. In some embodiments, the interposer 101 can comprise a single crystal semiconductor material. In some embodiments, the interposer 101 has a smaller footprint than that of the laminate substrate 103. In some embodiments, the interposer 101 is devoid of active circuitry (e.g., transistors). In other embodiments, the interposer 101 can comprise active circuitry. In some embodiments, the laminate substrate 103 has high density interconnections within the substrate, relative to the laminate substrate 103. In some embodiments, the electrically nonconductive adhesive layer 102 can be formed of a strong adhesive between the silicon portion of an interposer 101 and a PCB. In some embodiments, a coefficient of thermal expansion of the nonconductive material (e.g., Si) of the interposer 101 substantially matches that of the laminate substrate 103 (e.g., PCB).

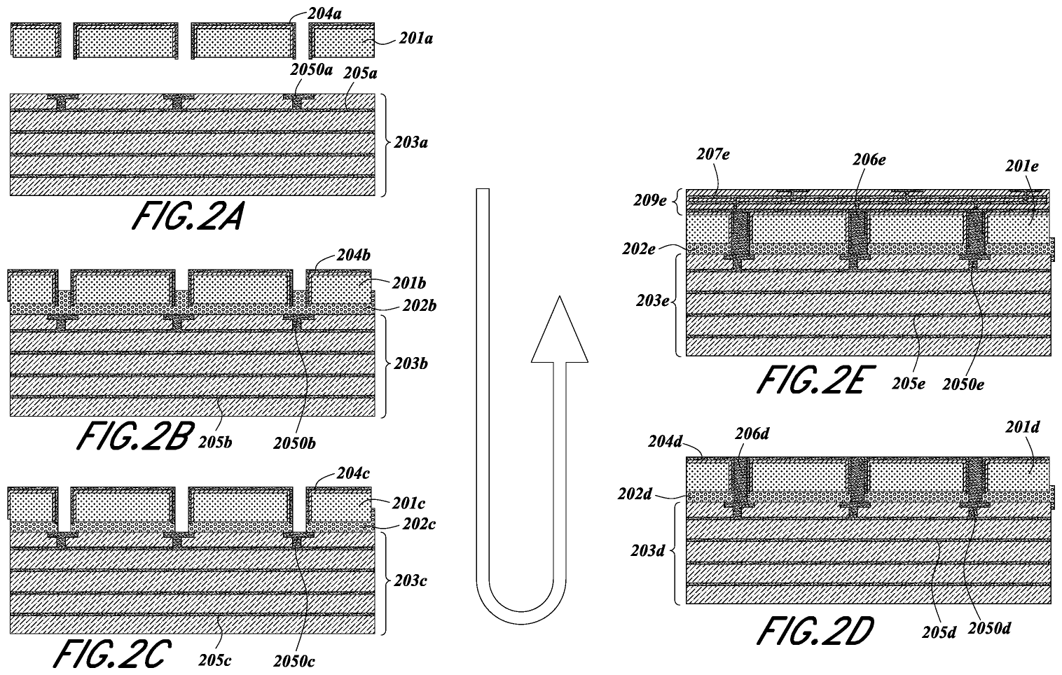

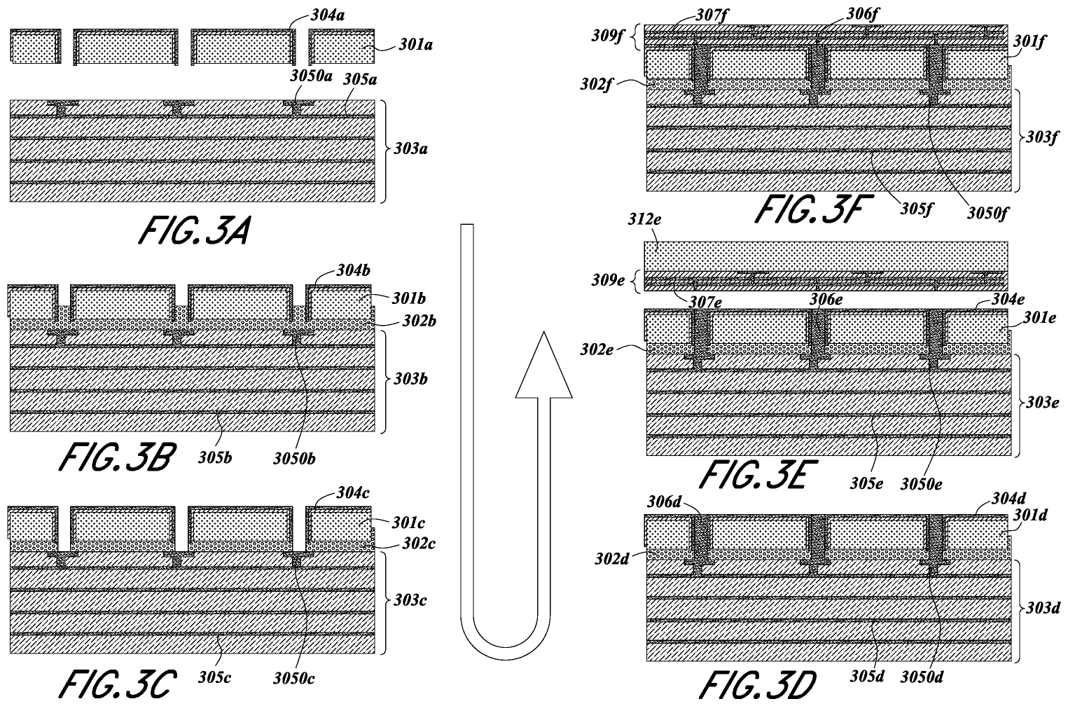

FIGS. 2A-E illustrate a process of forming a stacked structure shown in FIG. 1, where like features are referenced by like reference numbers incremented by 100, with suffixes to designate features at different process stages. The process can start with, as shown in FIG. 2A, providing a laminate substrate 203a and an interposer 201a. The interposer 201a can have a mounting surface configured to support an electronic device and a back surface opposite the mounting surface. The interposer 201a can further comprise a plurality of through vias formed in a nonconductive material. The interposer 201a can further comprise barrier materials 204a, and can also include metallization (traces, vias, pads) for local connections or routing other than simple through vias. The laminate substrate 203a may comprise metallic traces 205a and contact pads 2050a. The process can move to, as shown in FIG. 2B, bonding, adhering or otherwise integrating the back surface of the interposer 201b to the laminate substrate 203b, in the illustrated embodiment by way of a nonconductive adhesive layer 202b. The process can move to, as shown in FIG. 2C, removing a portion of the adhesive 202c from the plurality of through vias (e.g., by CO₂ laser ablation) to expose a plurality of contact pads 2050c in the laminate substrate 203c. The process can move to, as shown in FIG. 2D, metallizing the plurality of through vias to form a plurality of conductive vias 206d. The plurality of conductive vias 206d may be formed such that they are in contact with the contact pads 2050d of the laminate substrate 203d. The process can move to, as shown in FIG. 2E, forming a redistribution layer (RDL) 209e on the interposer 201e after bonding the back surface of the interposer 201e to the laminate substrate 203e. Forming the redistribution layer 209e may involve growing or depositing the redistribution layer 209e on the interposer 201e. As will be appreciated by the skilled artisan, forming RDL involves depositing and patterning insulating layer(s) and conductive layer(s), such that the redistribution layer 209e includes conductors 207e (e.g., vias, traces, pads) embedded in an insulating material and in electrical communication with the underlying conductive vias 206e through the interposer 201e.

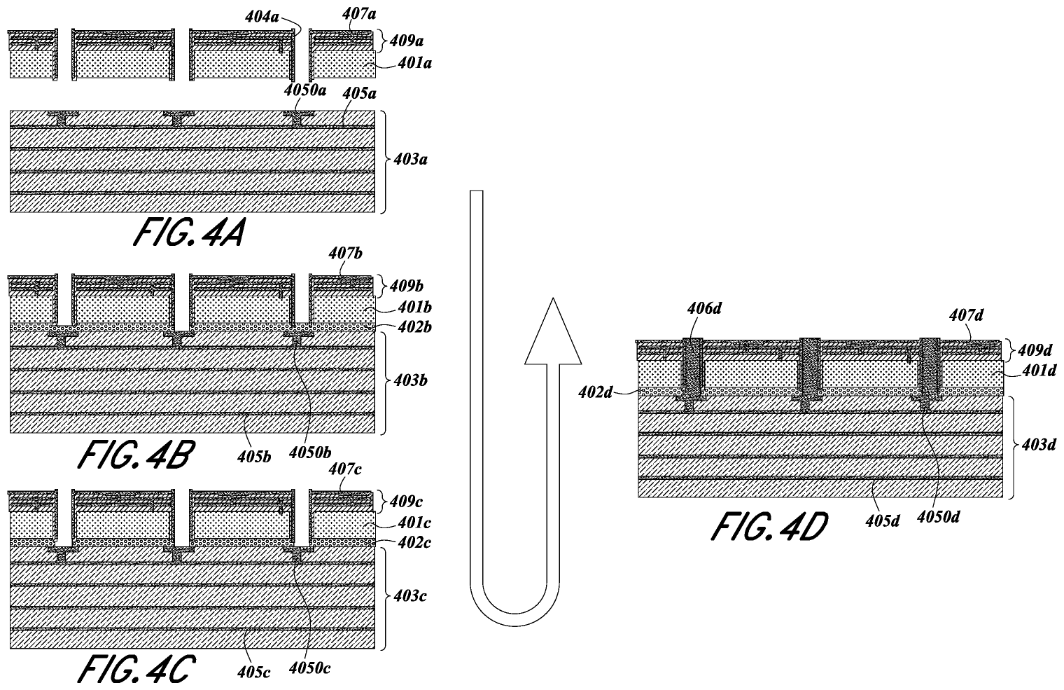

FIGS. 3A-F illustrates another process of forming a stacked structure shown in FIG. 1, where like features are referenced by like reference numbers incremented by 200, with suffixes to designate features at different process stages. The process can start with, as shown in FIG. 3A, providing a laminate substrate 303a and an interposer 301a. The interposer 301a can have a mounting surface configured to support an electronic device and a back surface opposite the mounting surface. The interposer 301a can further comprise a plurality of through vias formed in a nonconductive material. The interposer 301a can further comprise barrier materials 304a, and can also include metallization (traces, vias, pads) for local connections or routing other than simple through vias. The laminate substrate 303a may comprise metallic traces 305a and contact pads 3050a. The process can move to, as shown in FIG. 3B, bonding, adhering or otherwise integrating the back surface of the interposer 301b to the laminate substrate 303b, in the illustrated embodiment by way of a nonconductive adhesive layer 302b. The process can move to, as shown in FIG. 3C, removing a portion of the adhesive 302c from the plurality of through vias to expose a plurality of contact pads 3050c in the laminate substrate 303c. The process can move to, as shown in FIG. 3D, metallizing the plurality of through vias to form a plurality of conductive vias 306d. The plurality of conductive vias 306d may be formed such that they are in contact with the contact pads 3050d of the laminate substrate 303d. The process can move to forming a redistribution layer on the interposer after bonding the back surface of the interposer to the laminate substrate. Up to this point, the process of FIGS. 3A-3D can be similar to that described for FIGS. 2A-2D.

In this embodiment, forming the redistribution layer can be achieved by way of a transfer process, as shown in FIG. 3E and FIG. 3F. For example, as shown in FIG. 3E, forming the redistribution layer may involve providing a preformed RDL 309e and bonding the preformed RDL 309e to the interposer 301e by an intervening adhesive (not shown). The redistribution layer 309e may include conductors 307e (e.g., traces, vias, pads) embedded in an insulating material. Alternatively, forming the redistribution layer may involve providing a preformed RDL and directly bonding the preformed RDL to the interposer without an intervening adhesive (e.g., by a hybrid direct bonding process). The performed RDL 309e can be formed on a carrier 312e (such as a semiconductor or glass carrier). As shown in FIG. 3F, the carrier 312e can be removed from the RDL 309f after transferring the RDL 309f to the interposer 301f. Example RDL transfer processes are described in U.S. patent application Ser. No. 17/171,351, the content of which is hereby incorporated by reference herein in its entirety and for all purposes.

FIGS. 4A-D illustrates yet another process of forming a stacked structure shown in FIG. 1, where like features are referenced by like reference numbers incremented by 300, with suffixes to designate features at different process stages. In some examples, the process can start with, as shown in FIG. 4A, providing a laminate substrate 403a and an interposer 401a. The interposer 401a can have a mounting surface configured to support an electronic device and a back surface opposite the mounting surface. The laminate substrate 403a may comprise metallic traces 405a and contact pads 4050a. Next, the process can move to forming a redistribution layer (RDL) 409a on the mounting surface of the interposer 401a. As will be appreciated by the skilled artisan, forming RDL involves depositing and patterning insulating layer(s) and conductive layer(s), such that the redistribution layer 409a includes conductors 407a (e.g., vias, traces, pads) embedded in an insulating material. In some embodiments, a plurality of through vias extend through both the interposer 401a and the RDL 409a, and can be lined with barrier materials 404a as shown. The process can move to, as shown in FIG. 4B, bonding, adhering or otherwise integrating the back surface of the interposer 401b to the laminate substrate 403b, in the illustrated embodiment by way of a nonconductive adhesive layer 402b. The process can move to, as shown in FIG. 4C, removing a portion of the adhesive 403c from the plurality of through vias to expose a plurality of contact pads 4050c in the laminate substrate 403c. The process can move to, as shown in FIG. 4D, metallizing the plurality of through vias to form a plurality of conductive vias 406d which extend through both the interposer 401d and the RDL 409d, and connect to the conductors 407d of the RDL 409d to the contact pads 4050d of the laminate substrate 403d.

Following the processes illustrated in FIGS. 2A-2E, FIGS. 3A-3F, or FIGS. 4A-4D, at least one integrated device die can be attached onto the redistribution layer, by way of solder bonding, adhesive bonding, or direct bonding without an intervening adhesive. In some examples where the integrated device die is attached to the redistribution layer by way of solder bonding, an underfill may further be provided between the integrated device die and the redistribution layer. The underfill may have the capability to flow in between the die and the redistribution layer to provide mechanical protection of the solder ball joinings. In some embodiments, the underfill may be a composite which includes an epoxy that is filled with low coefficient of thermal expansion (CTE) particles, such as glass beads, to lower the overall CTE of the composite after hardening.

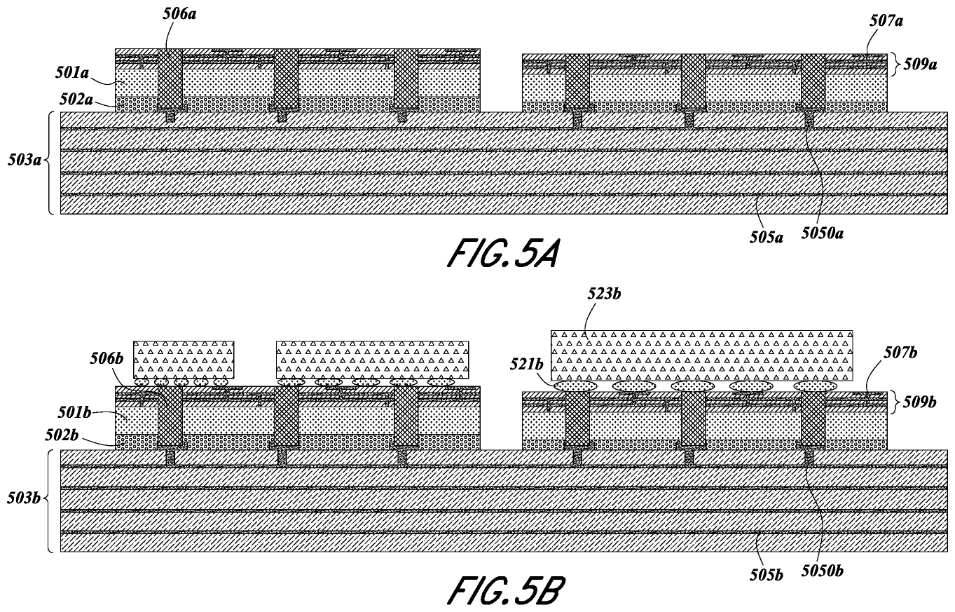

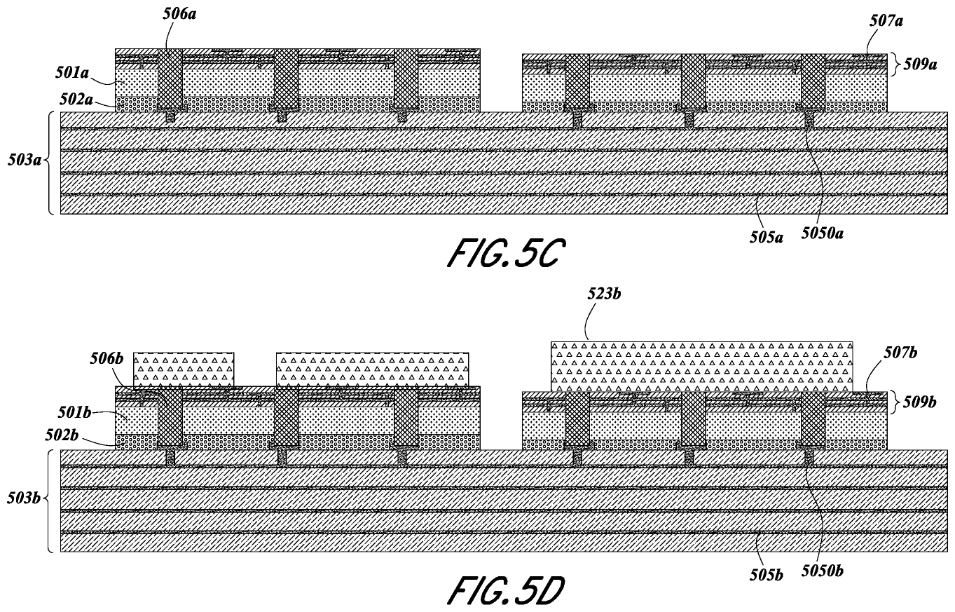

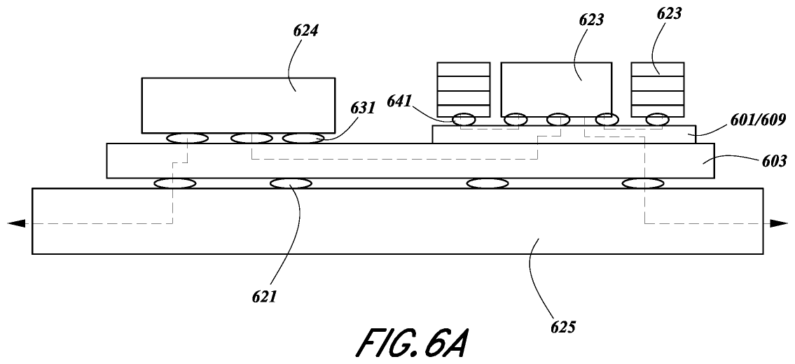

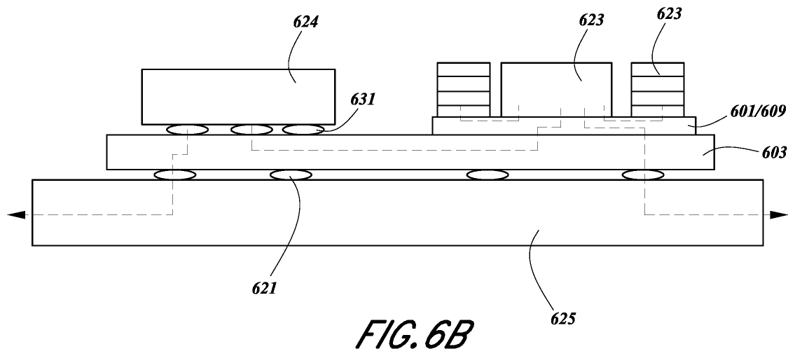

In some stacked structures as shown in FIG. 5A and FIG. 5B, where like features to those of FIG. 1 are referenced by like reference numbers incremented by 400, with suffixes to designate features at different process stages, more than one interposer is integrated with a laminate substrate. The more than one interposer 501a, 501b may be integrated with the substrate 503a, 503b by more than one respective adhesive layer 502a, 502b. Alternatively, the more than one interposer may be integrated with the substrate by a common continuous or patterned adhesive. At least one integrated device die 523b can be attached to the same RDL (e.g., 509a or 509b). For example, integrated device die 523b may be integrated and electrically connected to the RDL 509b, in the illustrated embodiment by solder balls 521b. As described above, the laminate substrate 503a, 503b may comprise metallic traces 505a, 505b and contact pads 5050a, 5050b. The RDL 509a, 509b may include conductors 507a, 507b (e.g., traces, vias, pads). The interposer 501a, 501b may be bonded, adhered or otherwise integrated to the laminate substrate 503a, 503b, in the illustrated embodiment by adhesive 502a, 502b. A plurality of conductive vias 506a, 506b through the interposer 501a, 501b may be in contact with the contact pads 5050a, 5050b of the laminate substrate, and may extend through both the interposer 501a, 501b and the RDL 509a, 509b as shown in FIGS. 4A-5B, or may extend through the interposer and connect with overlying RDL as shown in FIGS. 1-3F. In some embodiments, one or more RDLs and interposers mounted to the same substrate can comprise the same or generally similar structure. In some embodiments, one or more RDLs and interposers mounted to the same substrate can comprise different structures. In some embodiments, one or more RDLs and interposers mounted to the same substrate can comprise functionally similar structures. In some embodiments, one or more RDLs and interposers mounted to the same substrate can comprise functionally different structures.

FIGS. 5C-5D illustrate stacked structures similar to those of FIGS. 5A and 5B, and like reference numbers are used to reference like features. The difference is that FIGS. 5C-5D illustrate integrated device dies 523b direct hybrid bonded to the RDL 509b of or on the interposer 509b, without intervening solder or other adhesive layers.

As shown in FIG. 6A, the disclosed stacked structures may be used in packages systems to provide a signal pathway that transfers a signal from the laminate substrate 603, through an interposer 601 by some of the conductive vias, through the redistribution layer 609, to an integrated device die 623 (e.g., CPU, GPU, memory stacks, etc.), and in the opposite direction. The integrated device dies 623 may be soldered to redistribution layers 609 by solder balls 641, and may communicate with one another through the redistribution layer(s) 609. FIG. 6A also shows another integrated device die 624 that is directly connected to the laminate substrate 603 by way of additional solder balls 631. The laminate substrate 603 may be soldered to a system board 625 by solder balls 621. This integrated device die 624 is shown communicating with the other device dies 623 by way of the RDL 609, interposer 601 and laminate substrate 603. The disclosed stacked structures thus may also provide a signal pathway that transfers a signal from an integrated device die, through the redistribution layer, to another integrated device die, connected to the redistribution layer(s) or to the laminate substrate, and in the other direction. The interposer 601 is electrically and mechanically connected to the laminate substrate 603 without solder.

FIG. 6B is similar to FIG. 6A, except that the integrated device dies 623 are shown direct hybrid bonded to the RDL 609 on the interposer 601.

### Redistribution Layer

Integrated device packages can use a redistribution layer (RDL) to redistribute signals from one or more integrated device dies in the package to other devices (e.g., other devices outside the footprint of the integrated device die). The RDL can include traces that extend laterally, for connecting pads on top that are laterally offset with respect to pads on the bottom. Such lateral extension can connect features on the bottom and top of the RDL that have different pitches (fan-out or fan-in), simply laterally offset and/or can electrically connect multiple dies. The RDL may comprise conductors embedded in an insulating or nonconductive material. An electronic component (e.g., an integrated device die) can be connected to a redistribution layer, which can comprise conductive routing traces to route signals laterally outside the footprint of the electronic component. In some embodiments, the RDL comprises metallic traces or conductors extending laterally in order to transfer signals inwardly (fan-in) or outwardly (fan-out) from integrated device dies mounted to the RDL. In some embodiments, the interconnect structure may comprise one or a few layers. Beneficially, the RDL can include numerous or dense interconnects and signal lines that can convey a significant number of signals between the dies.

In some embodiments, fan-out redistribution can convey signals from finely-pitched bond pads of an integrated device die to other devices laterally spaced from the die. In some implementations, fan-out RDL can convey signals from dense contacts of a die to more spread out leads or contact pads configured to connect to a system board (e.g., a printed circuit board, or PCB). In some implementations, \ fan-out RDL can convey signals from the die to other devices, such as other integrated device dies, etc. In some packages that include multiple integrated device dies, the dies may be mounted to a sacrificial carrier, and a molding compound can be provided over the dies and carrier. The sacrificial carrier can be removed, and the molded device dies can be flipped over. The RDL can be deposited over the molding compound and the device dies to form a reconstituted wafer. The reconstituted wafer can be singulated into a plurality of packages, with each package including one or multiple dies connected to an RDL.

### Integrated Device Dies

In some embodiments, one or more of the plurality of integrated device dies can be flip-chip mounted to the RDL. The plurality of integrated device dies can comprise any suitable type of device die. For example, one or more of the plurality of integrated device dies can comprise an electronic component such as a processor die, a memory die, a microelectromechanical systems (MEMS) die, an optical device, or any other suitable type of device die. In other embodiments, the electronic component can comprise a passive device such as a capacitor, inductor, or other surface-mounted device. Circuitry (such as active components like transistors) can be patterned at or near active surface(s) of one or more of the plurality of integrated device dies in various embodiments. The active surfaces may be on a side of one or more of the plurality of integrated device dies which is opposite respective backsides of the one or more of the plurality of integrated device dies. The backsides may or may not include any active circuitry or passive devices. In various embodiment, the integrated device dies mounted to a substrate may be the same type of integrated device die or a different type of device die.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the RDL without an intervening adhesive, and the non-conductive material of the integrated device die can be directly bonded to a portion of the corresponding non-conductive material of the RDL without an intervening adhesive. Directly bonding without an adhesive is described further below, and in U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes. In some embodiments, the plurality of integrated device dies can alternatively be bonded to the RDL by way of a thermal conductive bonding (TCB).

### Examples of Direct Bonding Methods and Directly Bonded Structures

Various embodiments disclosed herein relate to directly bonded structures in which two elements can be directly bonded to one another without an intervening adhesive. Two or more elements (such as integrated device dies, wafers, interposers, redistribution layers, etc.) may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one aspect, a stacked structure is disclosed. The stacked structure can include a laminate substrate. The stacked structure can also include an interposer mounted on the laminate substrate by an adhesive layer. A plurality of conductive vias are extending through the interposer and the nonconductive adhesive layer and connecting to the laminate substrate. The stacked structure can also include a redistribution layer (RDL) adjacent to the interposer.

In one embodiment, the RDL is on the interposer.

In one embodiment, the RDL is between the interposer and the adhesive layer.

In one embodiment, the stacked structure further includes an additional RDL between the interposer and the adhesive layer.

In one embodiment, the RDL is configured to electrically connect to an electronic device.

In one embodiment, the plurality of conductive vias extend through the redistribution layer.

In one embodiment, the interposer comprises a nonconductive material formed of glass, semiconductor and/or ceramic.

In one embodiment, the redistribution layer comprises conductors embedded in an insulating material.

In one embodiment, the redistribution layer is grown or deposited on the interposer.

In one embodiment, the redistribution layer is integrated with the interposer by an intervening adhesive.

In one embodiment, the redistribution layer is directly bonded to the interposer without an intervening adhesive.

In one embodiment, the stacked structure further includes at least one integrated device die arranged on the redistribution layer.

In one embodiment, the at least one integrated device die is electrically connected to the redistribution layer.

In one embodiment, the at least one integrated device die is integrated with the redistribution layer by soldering.

In one embodiment, the at least one integrated device die is integrated with the redistribution layer by an intervening adhesive.

In one embodiment, the at least one integrated device die is directly bonded to the redistribution layer without an intervening adhesive.

In one embodiment, the laminate substrate comprises a printed circuit board and/or wherein the laminate substrate comprises ceramic.

In one embodiment, the adhesive layer comprises an electrically nonconductive adhesive and/or an underfill.

In one embodiment, the stacked structure can also include a signal pathway configured to transfer a signal from the laminate substrate, through the interposer by way of the plurality of conductive vias, through the redistribution layer, to one of the at least one integrated device die, and vice versa.

In one embodiment, the stacked structure can also include a signal pathway configured to transfer a signal from one of the at least one integrated device die, through the redistribution layer, to another one of the at least one integrated device die, and vice versa.

In one embodiment, the stacked structure can also include an additional redistribution layer arranged between the interposer and the laminate substrate.

In one embodiment, the interposer is devoid of active circuitry.

In one embodiment, the RDL is disposed over the plurality of conductive vias.

In one embodiment, the plurality of conductive vias extend through from the interposer to the RDL.

In one aspect, a stacked structure is disclosed. The stacked structure can include a laminate substrate. The stacked structure can also include at least two interposers arranged on the laminate substrate. Each of the at least two interposers are integrated with the laminate substrate by one or more nonconductive adhesive layers.

In one embodiment, each of the at least two interposers comprises a respective plurality of conductive vias formed in a nonconductive material.

In one embodiment, the stacked structure can also include a respective redistribution layer arranged on each of the at least two interposers.

In one embodiment, the stacked structure can also include a respective redistribution layer arranged on each of the at least two interposers. The respective plurality of conductive vias extends through the respective redistribution layer.

In one embodiment, the nonconductive material is formed of glass, semiconductor and/or ceramic.

In one embodiment, the respective redistribution layer comprises conductors embedded in an insulating material.

In one embodiment, the respective redistribution layer is grown or deposited on the interposer.

In one embodiment, the respective redistribution layer is integrated with the interposer by an intervening adhesive.

In one embodiment, the respective redistribution layer is directly bonded to the interposer without an intervening adhesive.

In one embodiment, the stacked structure can also include at least one integrated device die arranged on the respective redistribution layer.

In one embodiment, the at least one integrated device die is integrated with the respective redistribution layer by soldering.

In one embodiment, the at least one integrated device die is integrated with the respective redistribution layer by an intervening adhesive.

In one embodiment, the at least one integrated device die is directly bonded to the respective redistribution layer without an intervening adhesive.

In one embodiment, the laminate substrate is a printed circuit board and/or wherein the laminate substrate comprises ceramic.

In one embodiment, the respective adhesive layer comprises an electrically nonconductive adhesive and/or an underfill.

In one embodiment, the stacked structure can also include a signal pathway configured to transfer a signal from the laminate substrate, through one of the at least two interposers by way of the respective plurality of conductive vias, through the respective redistribution layer, to one of the at least one integrated device die, and vice versa.

In one embodiment, the stacked structure can also include an additional redistribution layer arranged between one of the at least two interposers and the laminate substrate.

In one aspect, a method of forming a stacked structure is disclosed. The method can include providing a laminate substrate. The method can also include providing an interposer. The interposer is having a mounting surface configured to support an electronic device and a back surface opposite the mounting surface. The method can include integrating the interposer with the laminate substrate without solder. A plurality of conductive vias extend through the interposer to connect to the laminate substrate.

In one embodiment, the interposer comprises a plurality of through vias formed in a nonconductive material.

In one embodiment, the method can also include forming a redistribution layer on the interposer after bonding the back surface of the interposer to the laminate substrate.

In one embodiment, the method can also include forming a redistribution layer on the interposer before bonding the back surface of the interposer to the laminate substrate.

In one embodiment, the plurality of through vias extends through the redistribution layer.

In one embodiment, the nonconductive material is formed of glass, semiconductor and/or ceramic.

In one embodiment, integrating the interposer with the laminate substrate includes providing a nonconductive adhesive, and the method includes removing a portion of the adhesive from the plurality of through vias to expose a plurality of contact pads in the laminate substrate. The method can also include metallizing the plurality of through vias to form a plurality of conductive vias.

In one embodiment, the redistribution layer comprises conductors embedded in an insulating material.

In one embodiment, forming the redistribution layer comprises growing or depositing the redistribution layer on the interposer.

In one embodiment, forming the redistribution layer comprises bonding the redistribution layer to the interposer by an intervening adhesive, where the redistribution layer has been preformed.

In one embodiment, forming the redistribution layer comprises directly bonding the redistribution layer to the interposer without an intervening adhesive, where the redistribution layer has been preformed.

In one embodiment, the method can also include attaching at least one integrated device die onto the redistribution layer.

In one embodiment, attaching the at least one integrated device die comprises solder bonding the at least one integrated device die to the redistribution layer.

In one embodiment, attaching the at least one integrated device die comprises adhesive bonding the at least one integrated device die to the redistribution layer.

In one embodiment, attaching the at least one integrated device die comprises direct bonding the at least one integrated device die to the redistribution layer without an intervening adhesive.

In one embodiment, the laminate substrate comprises a printed circuit board and/or wherein the laminate substrate comprises ceramic.

In one embodiment, integrating the interposer with the laminate substrate includes providing an underfill.

In one embodiment, the method can also include providing an additional redistribution layer between the interposer and the laminate substrate.

In one embodiment, integrating the interposer with the laminate substrate includes providing a nonconductive adhesive, and the method also includes removing a portion of the adhesive from the plurality of through vias and metallizing the plurality of through vias are subsequent to bonding the back surface of the interposer to the laminate substrate.

In one embodiment, the interposer has a smaller footprint than that of the laminate substrate.

In one embodiment, each of the at least two interposers has a smaller footprint than that of the laminate substrate.

In one embodiment, a coefficient of thermal expansion of the nonconductive material substantially matches that of the laminate substrate.

In one embodiment, the redistribution layer has a line spacing less than 5 microns.

In one embodiment, each of the at least two redistribution layers has a line spacing less than 5 microns.

In one aspect, a stacked structure is disclosed. The stacked structure can include a laminate substrate. The stacked structure can also include a substrate mounted on the laminate substrate without solder. A plurality of conductive vias extend through the substrate and connect to the laminate substrate. The stacked structure can also include a redistribution layer (RDL) adjacent to the substrate.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A stacked structure, comprising:
a laminate substrate;
an interposer mounted on the laminate substrate by an adhesive layer, a plurality of conductive vias extending through the interposer and the nonconductive adhesive layer and connecting to the laminate substrate; and
a redistribution layer (RDL) adjacent to the interposer.

2. The stacked structure of claim 1, wherein the RDL is on the interposer.

3. The stacked structure of claim 1, wherein the RDL is between the interposer and the adhesive layer.

4. The stacked structure of claim 2, further comprising an additional RDL between the interposer and the nonconductive adhesive layer.

5. The stacked structure of claim 1, wherein the plurality of conductive vias extend through the redistribution layer.

6. The stacked structure of claim 1, wherein the interposer comprises a nonconductive material formed of glass, semiconductor and/or ceramic.

7. The stacked structure of claim 1, wherein the redistribution layer is integrated with the interposer by an intervening adhesive.

8. The stacked structure of any one of claim 1, wherein the redistribution layer is directly bonded to the interposer without an intervening adhesive.

9. A stacked structure comprising:
a laminate substrate; and
at least two interposers arranged on the laminate substrate,
wherein each of the at least two interposers are integrated with the laminate substrate by one or more nonconductive adhesive layers.

10. The stacked structure of claim 9, wherein each of the at least two interposers comprises a respective plurality of through interposer conductive vias formed in a nonconductive material.

11. A method of forming a stacked structure, the method comprising:
providing a laminate substrate;
providing an interposer, the interposer having a mounting surface configured to support an electronic device and a back surface opposite the mounting surface; and
integrating the interposer with the laminate substrate without solder, wherein a plurality of conductive vias extend through the interposer to connect to the laminate substrate.

12. The method of claim 11, wherein the interposer is integrated with the laminate substrate by way of an adhesive layer, wherein the plurality of conductive vias extend through the adhesive layer.

13. The method of claim 11, further comprising forming a redistribution layer on the interposer after integrating the interposer with the laminate substrate.

14. The method of claim 11, further comprising forming a redistribution layer on the interposer before integrating the interposer with the laminate substrate.

15. The method of claim 12, further comprising:
removing a portion of the adhesive layer to expose a plurality of contact pads in the laminate substrate; and
metallizing a plurality of through vias in the interposer aligned with the plurality of contact pads to form the plurality of conductive vias.

16. The method of claims 13, wherein forming the redistribution layer comprises bonding the redistribution layer to the interposer by an intervening adhesive, wherein the redistribution layer has been preformed.

17. The method of claims 13, wherein forming the redistribution layer comprises directly bonding the redistribution layer to the interposer without an intervening adhesive, wherein the redistribution layer has been preformed.

18. A stacked structure, comprising:
a laminate substrate; and
a substrate mounted on the laminate substrate without solder, a plurality of conductive vias extending through the substrate and connecting to the laminate substrate; and
a redistribution layer (RDL) on a side of the substrate opposite the laminate substrate.
